(19) United States
(12) Patent Application Publication
(10) Pub. No.: US 2024/0371759 A1
(43) Pub. Date: Nov. 7, 2024

(54) Semiconductor Device and Method of Making a Multi-Tier System-in-Package

(71) Applicant: JCET STATS ChipPAC Korea Limited, Incheon (KR)

(72) Inventors: SeungHyun Lee, Incheon (KR); YeJin Park, Incheon (KR); HunTeak Lee, Gyeonggi-do (KR); HeeSoo Lee, Incheon (KR)

(73) Assignee: JCET STATS ChipPAC Korea Limited, Incheon (KR)

(21) Appl. No.: 18/312,133

(22) Filed: May 4, 2023

(51) Int. Cl. H01L 23/528; H01L 21/56; H01L 21/768; H01L 23/31; H01L 23/498; H01L 23/66

(52) U.S. Cl. CPC H01L 23/5283; H01L 21/56; H01L 21/76898; H01L 23/3157; H01L 23/49816; H01L 23/66; H01L 2223/6677

(57) ABSTRACT

A semiconductor device has a first substrate and a first electrical component disposed over a first surface of the first substrate. A first encapsulant is deposited over the first electrical component and first surface of the first substrate. A modular interconnect unit is disposed over a second surface of the first substrate. A second encapsulant is deposited over the second surface of the first substrate. A second substrate is disposed over the second surface of the first substrate and electrically connected to the first substrate through the modular interconnect unit.

### FIELD OF THE INVENTION

The present invention relates in general to semiconductor devices and, more particularly, to a semiconductor device and method of making a multi-tier system-in-package.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, power conversion, photo-electric, and creating visual images for television displays. Semiconductor devices are found in the fields of communications, networks, computers, entertainment, and consumer products. Semiconductor devices are also found in military applications, aviation, automotive, industrial controllers, and office equipment.

Semiconductor devices may contain multiple electrical components, e.g., semiconductor die and discrete components, disposed on a substrate to perform necessary electrical functions. Such a package is commonly referred to as a system-in-package (SiP) module. SiP modules may integrate more advanced functionality by stacking multiple substrates over each other and mounting electrical components over and between each substrate.

Multi-tier SiP modules are difficult to construct and require highly tuned process steps and structural elements to ensure that the end product operates properly. The SiP module topologies currently available are reaching their limits as far as device and signal routing density. Therefore, a need exists for improved multi-tier integrated SiP methods and devices.

### BRIEF DESCRIPTION OF THE DRAWINGS

FIGS. 1a-1c illustrate a semiconductor wafer with a plurality of semiconductor die separated by a saw street;

FIGS. 2a-2m illustrate a process of forming a multi-tier SiP module;

FIGS. 3a-3j illustrate an alternative process of forming a multi-tier SiP module;

FIGS. 4a-4e illustrate forming antennae over the SiP module;

FIGS. 5a-5d illustrate alternative interconnect structures;

FIG. 6 illustrates the alternative interconnect structures in another embodiment;

FIGS. 7a-7d illustrate alternative embodiments of forming an antenna over the SiP module; and

FIGS. 8a and 8b illustrate an electronic device with the multi-tier SiP module.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

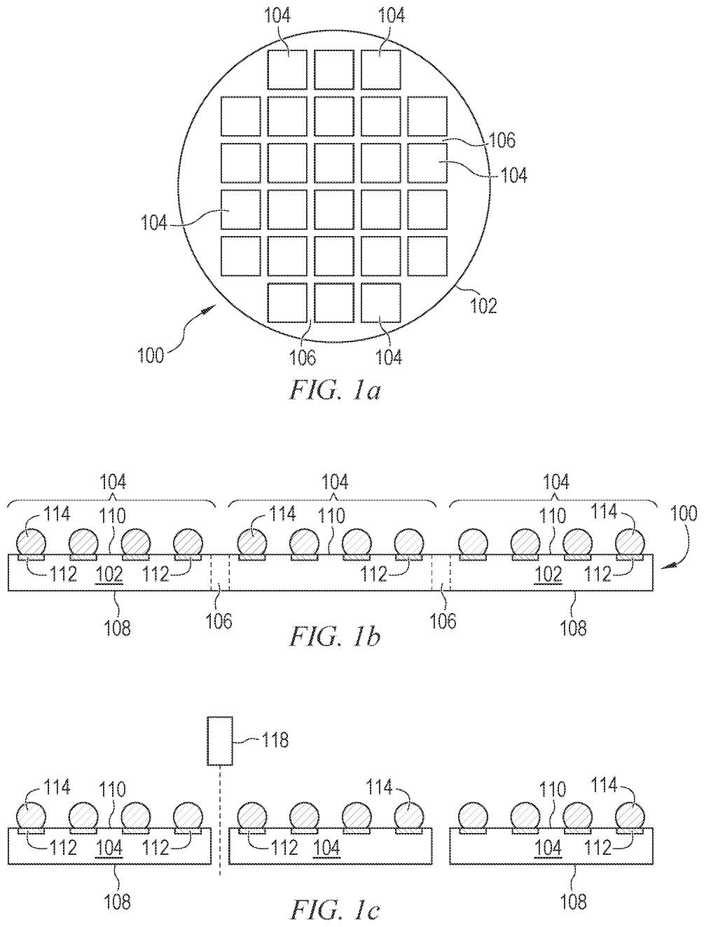

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesion layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or known good unit (KGD/KGU) post singulation.

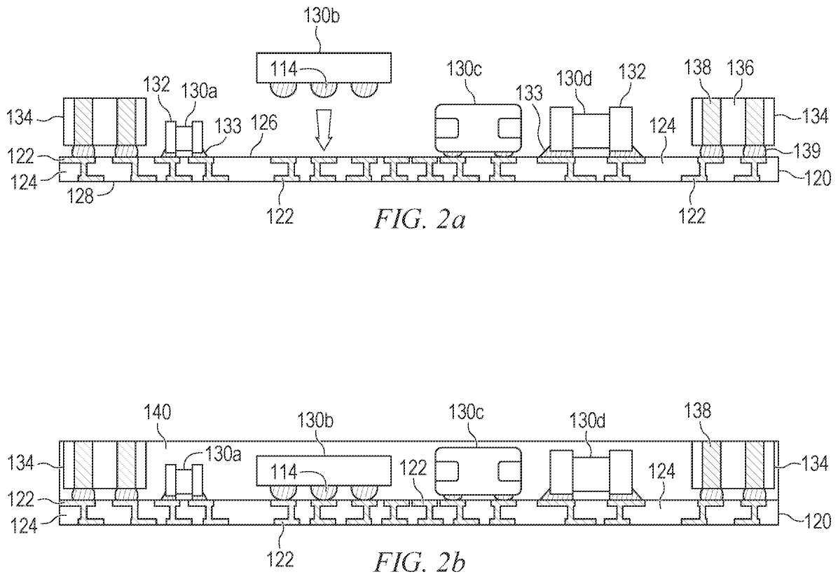

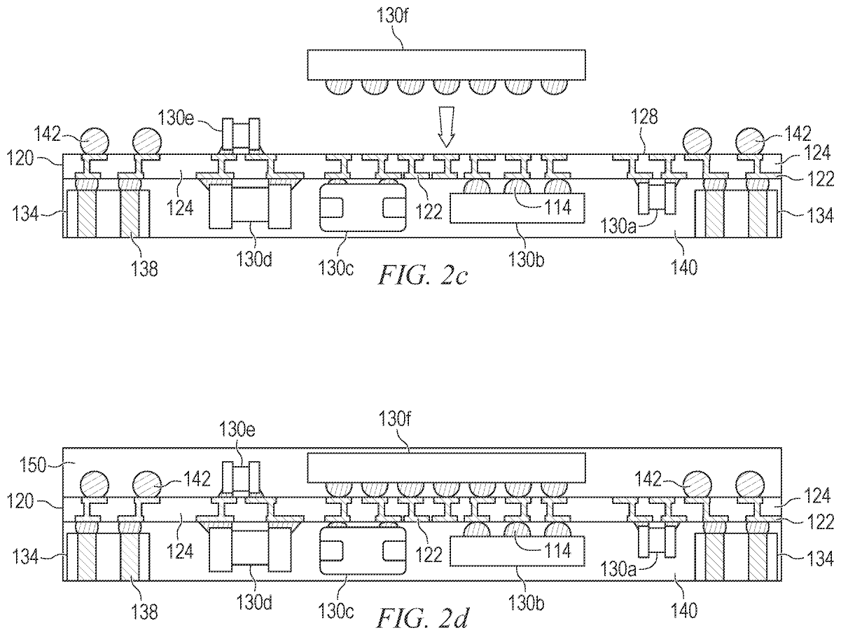

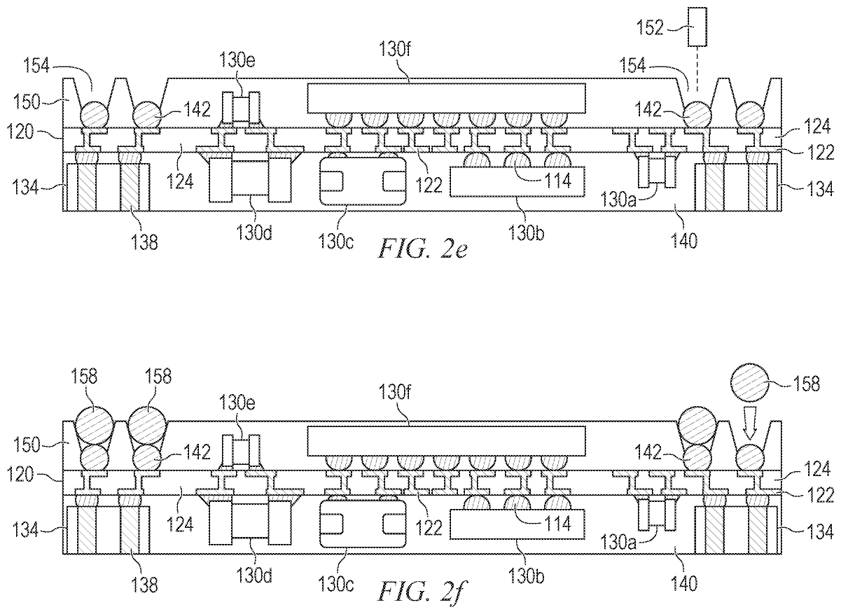

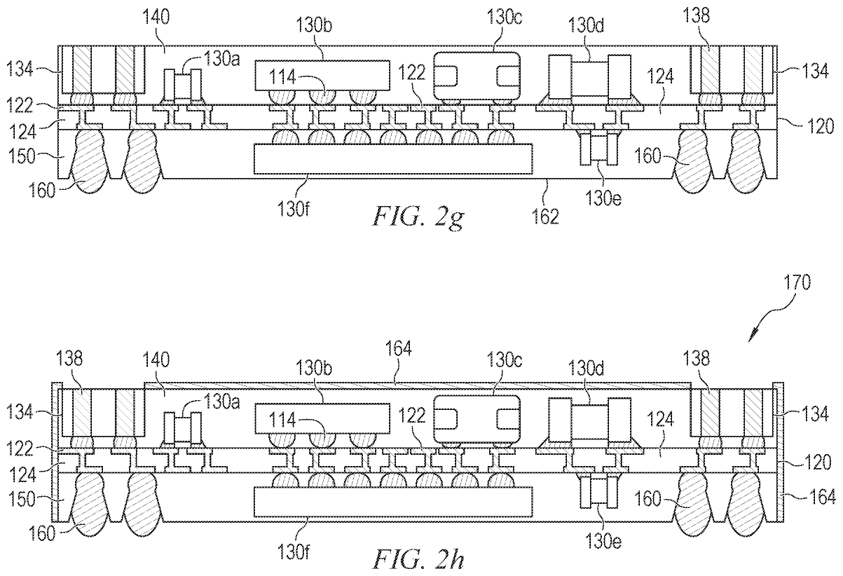

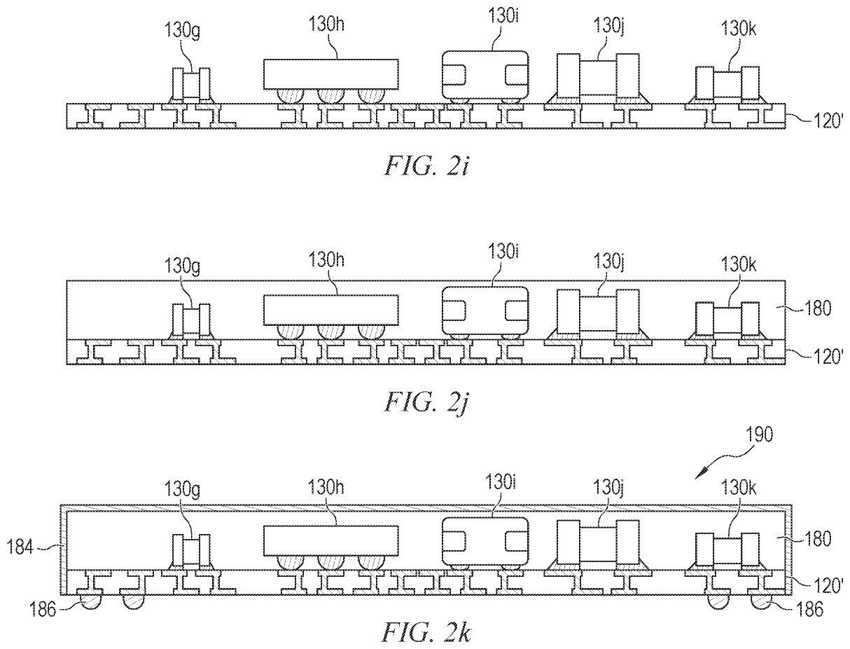

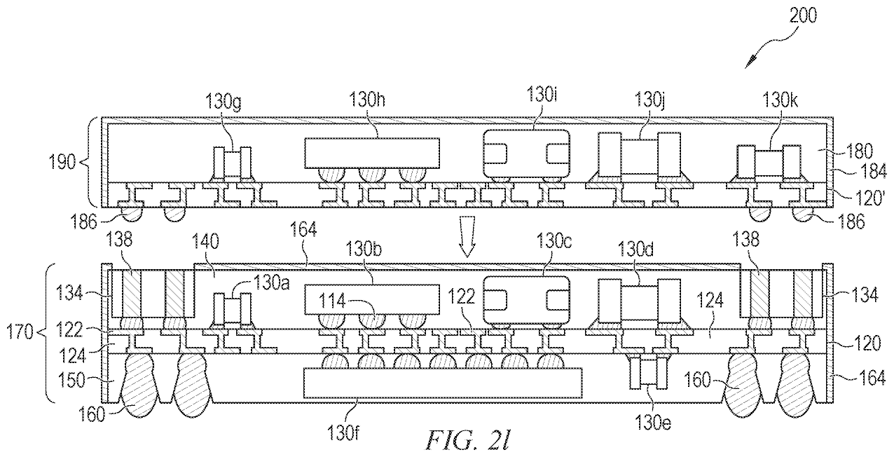

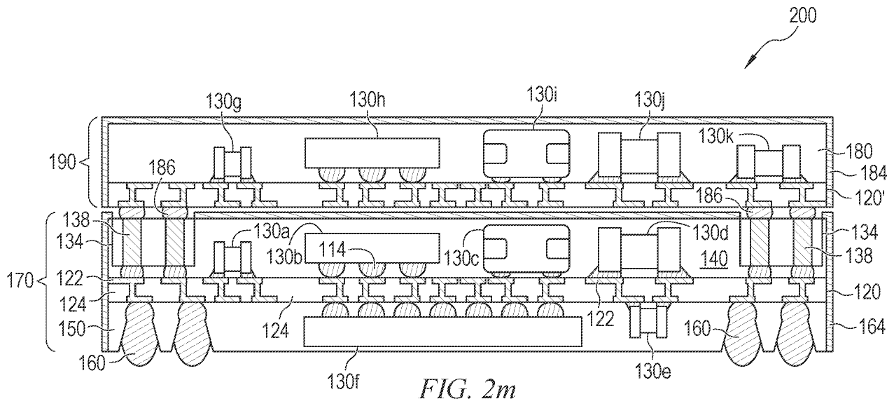

FIGS. 2a-2m illustrate a process of forming a multi-tier SiP module. FIG. 2a shows a cross-sectional view of multi-layered interconnect substrate 120 including conductive layers 122 and insulating layers 124. While only a single substrate 120 suitable to form a single semiconductor package is shown, hundreds or thousands of units are commonly manufactured and processed as part of a single substrate 120 before being singulated from each other, using the same steps described herein performed en masse. A separate substrate 120 could also be used for each unit being manufactured, the substrate being singulated before the steps shown in FIGS. 2a-2m and a plurality of individual substrates being placed on a common carrier for processing.

Conductive layer 122 can be one or more layers of Al, Cu, Sn, Ni, Au, Ag, or other suitable electrically conductive material. Conductive layers can be formed using PVD, CVD, electrolytic plating, electroless plating, or other suitable metal deposition process. Conductive layer 122 provides horizontal electrical interconnect across substrate 120 and vertical electrical interconnect between top surface 126 and bottom surface 128 of substrate 120. Portions of conductive layer 122 can be electrically common or electrically isolated depending on the design and function of semiconductor die 104 and other electrical components.

Insulating layer 124 contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Insulating layers can be formed using PVD, CVD, printing, lamination, spin coating, spray coating, sintering, or thermal oxidation. Insulating layer 124 provides isolation between conductive layers 122. Any number of conductive layers 122 and insulating layers 124 can be interleaved over each other to form substrate 120. Any other suitable type of package substrate or leadframe is used for substrate 120 in other embodiments.

Electrical components 130a-130d are disposed on surface 126 of interconnect substrate 120 and electrically and mechanically connected to conductive layers 122. For example, electrical components 130a, 130c, and 130d can be discrete electrical devices, such as a diode, transistor, resistor, capacitor, and inductor. Electrical component 130b can be, or be similar to, semiconductor die 104 from FIG. 1c with bumps 114 oriented toward surface 126 of substrate 120. Alternatively, electrical components 130a-130d can include other semiconductor die, semiconductor packages, surface mount devices, RF components, and discrete electrical devices. Any of the electrical components 130 can have integrated passive devices (IPDs) formed in or on the electrical components.

Electrical components 130a-130d are positioned over surface 126 of substrate 120 using a pick and place machine or operation. Electrical components 130a-130d are brought into contact with conductive layer 122 on surface 126 of substrate 120. Terminals 132 of electrical components 130a and 130d are electrically and mechanically connected to conductive layer 122 using solder or conductive paste 133. Electrical component 130b is electrically and mechanically connected to conductive layer 122 by reflowing bumps 114.

One or more PCB units, e-bars, or modular interconnect units 134 are disposed over substrate 120 in a similar manner to electrical components 130. Modular interconnect unit 134 is disposed onto substrate 120 using a pick-and-place machine or operation. Modular interconnect unit 134 includes an insulating core 136 and a plurality of conductive vias 138 extending through the insulating core. Solder bumps 139 are disposed between substrate 120 and conductive vias 138 and are reflowed to electrically and mechanically connect modular interconnect unit 134 to substrate 120. Modular interconnect unit 134 optionally includes contact pads, solder resist layers, or both formed over the top, bottom, or both surfaces of the modular interconnect unit. Modular interconnect unit 134 provides vertical interconnect from substrate 120, which will be explained in further detail below.

In FIG. 2b, encapsulant or molding compound 140 is deposited over and around electrical components 130a-130d and surface 126 of substrate 120 using a paste printing, compressive molding, transfer molding, liquid encapsulant molding, vacuum lamination, spin coating, or other suitable applicator. Encapsulant 140 can be liquid or granular polymer composite material, such as epoxy resin, epoxy acrylate, or another suitable polymer, with or without a suitable filler. Encapsulant 140 is non-conductive, provides structural support, and environmentally protects the semiconductor device from external elements and contaminants. A top surface of PCB units 134 is exposed from encapsulant 140, to allow for subsequent electrical interconnect, by using film-assisted molding or by backgrinding after deposition of the encapsulant.

In FIG. 2c, substrate 120 is flipped over and electrical components 130e and 130f are disposed over and mounted to bottom surface 128 of substrate 120. Electrical component 130e is similar to and mounted in a similar manner to electrical components 130a, 130c, and 130d. Electrical component 130f is a semiconductor die similar to electrical component 130b. Any suitable number and type of electrical components can be mounted onto either surface 126 or 128 of substrate 120 to implement the desired electrical function of a semiconductor package being formed. All of the electrical components 130 disposed on surfaces of substrate 120 are electrically interconnected to each other by conductive layer 122 as necessary to implement the intended functionality of the semiconductor package being formed.

Solder bumps 142 are disposed over surface 128 and mounted to contact pads of conductive layer 122. Solder bumps 142 are formed from similar materials and methods to bumps 114 being formed on semiconductor die 104 above. Bumps 142 will be used for external interconnect of the final semiconductor package to another electrical system.

In FIG. 2d, encapsulant or molding compound 150 is deposited over and around electrical components 130e-130f, solder bumps 142, and surface 128 of substrate 120. Deposition of encapsulant 150 can use any of the methods and materials described above for encapsulant 140. Encapsulant 150 completely covers the top surfaces of electrical components 130e-130f and solder bumps 142. In other embodiments, some electrical components 130 can remain exposed from encapsulant 150 or have surfaces that are coplanar to the encapsulant.

In FIG. 2e, a portion of encapsulant 150 is removed by chemical etching, mechanical drilling, or laser ablation using laser 152 to form vias or openings 154 and expose solder bumps 142. Additional solder bumps 158 are disposed into openings 154 in FIG. 2f. Bumps 158 can be any suitable conductive material and placed using any suitable solder ball placement means. Bumps 158 rest on bumps 142 or above bumps 142 on surfaces of encapsulant 150 within openings 154. Openings 154 are conical shaped in one embodiment to support spherical bumps 158.

FIG. 2g shows bumps 142 and 158 reflowed together to form a combined bump 160. Bump 160 includes solder material from bumps 142 and 158 reflowed into a single unitary bump. Bump 160 extends from contact pads of substrate 120 to above the top surface 162 of encapsulant 150. FIG. 2g also shows substrate 120 flipped over so that encapsulant 140 is oriented upward.

To address electromagnetic interference (EMI), radio frequency interference (RFI), harmonic distortion, and inter-device interference, a shielding layer 164 is optionally formed over a top surface of encapsulant 140 to reduce or inhibit the effects of EMI, RFI, and other inter-device interference, as shown in FIG. 2h. Shielding layer 164 is deposited, printed, sputtered, plated, or otherwise formed. Plating can be performed by CVD, PVD, other sputtering methods, electroplating, electroless plating, or another suitable metal deposition process. Shielding layer 164 includes one or more layers of Al, Cu, Sn, Ni, Au, Ag, stainless steel, or other suitable electrically conductive material.

When multiple packages are formed as a panel of devices over a single substrate 120, the panel is typically singulated through encapsulant 140, substrate 120, and encapsulant 150 into individual units 170 prior to forming shielding layer 164 so that side surfaces of the packages are exposed to the metal deposition process. Units 170 can be a package-on-package bottom package or a standalone system. Shielding layer 164 extending down side surfaces units 170 helps to protect from laterally incident EMI. Portions of conductive layer 122 are exposed at side surfaces of substrate 120 in some embodiments to physically and electrically connect to shielding layer 164, thereby grounding the shielding layer to improve performance.

Openings are formed through shielding layer 164 over PCB units 134 to expose conductive vias 138 and allow electrical connection to substrate 120 through the PCB units. Openings are formed by selective plating with shielding layer 164 being formed over encapsulant 140 without completely covering PCB units 134. Alternatively, a mask is formed over PCB units 134 before forming shielding layer 164 and then removed to expose the PCB units. Another option is to form shielding layer 164 over PCB units 134 and then removing portions of the shielding layer by laser ablation, chemical etching, or another suitable process.

Unit 170 in FIG. 2h can be used as a completed semiconductor package. Alternatively, FIGS. 2i-2k illustrate forming a package-on-package top package (PoPt) 190 that can be stacked on unit 170 to form a package-on-package (PoP) device. PoPt 190 is formed over a substrate 120′ as shown in FIG. 2. One or more apostrophes after a reference number indicates that the item being referred to is essentially identical to the same reference number without apostrophes but used in a different example or applied in a slightly different way. Substrate 120′ can be any of the embodiments described above for substrate 120. Substrate 120′ would typically, but not necessarily, be formed in the same methods and materials as substrate 120 for any given embodiment. The difference between substrates 120 and 120′ would be that the signal routing of conductive layers 122 is different to interconnect electrical components 130a-130f for substrate 120 and electrical components 130g-130k for substrate 120′.

Electrical components 130g-130k are disposed over substrate 120′ as described above for electrical components 130a-130f over substrate 120. Any suitable number and type of electrical component, such as semiconductor die or discrete active or passive electrical components can be mounted on substrate 120′.

Encapsulant 180 is deposited over substrate 120′ and electrical components 130g-130k in FIG. 2j. Encapsulant 180 can use any of the methods and materials described above for encapsulant 140. Encapsulant 180 completely covers the top surfaces of electrical components 130g-130k. In other embodiments, some electrical components 130 can remain exposed from encapsulant 180 or have surfaces that are coplanar to the encapsulant.

In FIG. 2k, a shielding layer 184 is formed over PoPt 190 as described above for shielding layer 164. In embodiments where substrate 120′ has a plurality of PoPt 190 units formed over a single larger substrate, the units can be singulated prior to forming shielding layer 184 to allow the shielding layer to extend down side surfaces of each unit. Bumps 186 are formed on contact pads of substrate 120′ opposite components 130g-130k as described above for bumps 114 on semiconductor die 104. Bumps 186 can be formed at any suitable stage in the manufacturing process. PoPt 190 can be a standalone system in some embodiments.

In FIG. 2l, PoPt 190 is disposed over and mounted to unit 170, which operates as a package-on-package bottom package (PoPb) to form a PoP 200. PoPt 190 is disposed over PoPb 170 with bumps 186 aligned over conductive vias 138. As PoPt 190 is lowered, bumps 186 physically contact vias 138. Bumps 186 are reflowed to electrically connect and mechanically attach PoPt 190 to PoPb 170.

FIG. 2m shows a completed PoP 200. Electrical components 130a-130k are electrically interconnected to each other by substrate 120, substrate 120′, and PCB units 134. Conductive vias or another alternative interconnect structure can be formed through encapsulant 140 instead of using prefabricated PCB units 134. Bumps 160 remain exposed for external interconnect to a larger electrical system. Shielding layers 164 and 184 in combination extend over and cover all externally facing top and side surfaces. The portion of shielding layer 164 on the top surface of encapsulant 140 extends between PoPt 190 and PoPb 170 to help block intra-device interference.

PoP 200 is a multi-tier system-in-package semiconductor package. The illustrated embodiment includes three tiers: one tier formed on substrate 120′, a second tier formed on top surface 126 of substrate 120, and a third tier formed on bottom surface 128 of substrate 120. In one embodiment, the top tier, formed on substrate 120′, is a Wi-fi and Bluetooth device, the middle tier formed on top surface 126 of substrate 120 is an ultra-wideband (UWB) device, and the lower tier formed on bottom surface 128 of substrate 120 is a global positioning system (GPS) device.

More tiers can be added by forming intermediate packages similar to PoPt 190 but including exposed PCB units 138 as with PoPb 170. PoPt 190 could also be formed with an additional tier over the bottom surface of substrate 120′ with additional PCB units 134 between bumps 186 and substrate 120′ to interconnect to the PCB units of PoPb 170. PoP 200 is formed in a streamlined process with reduced cost and increased reliability. PoP 200 has a higher integration of electronic functionality and performance, along with a smaller form factor, compared to the prior art.

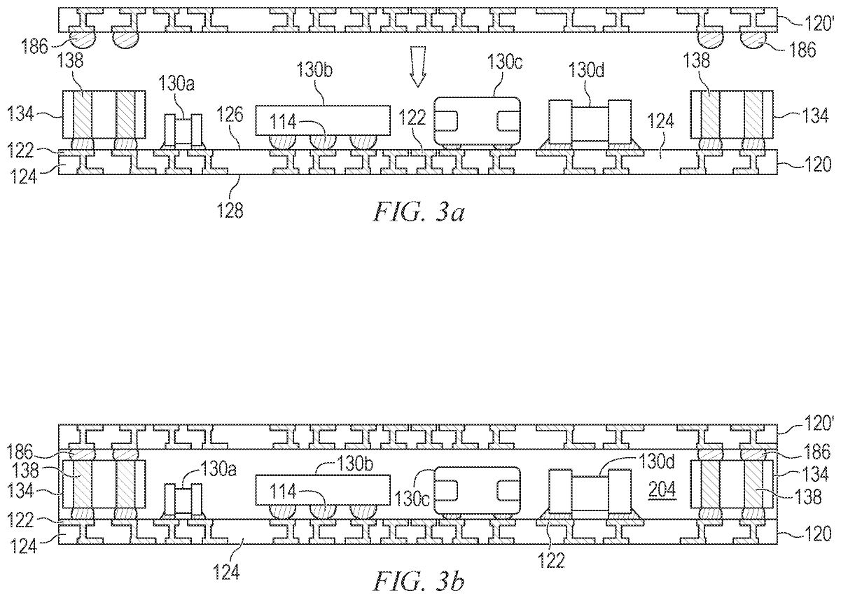

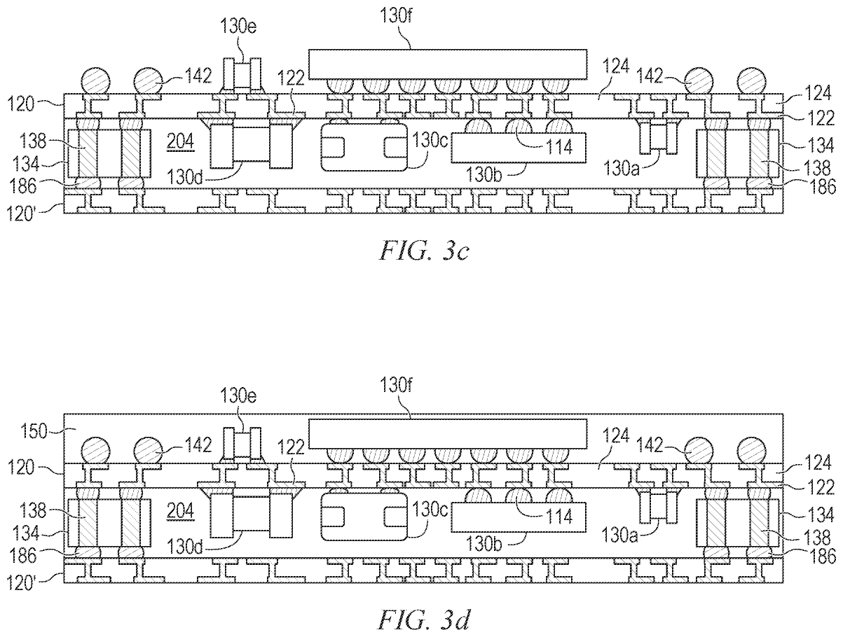

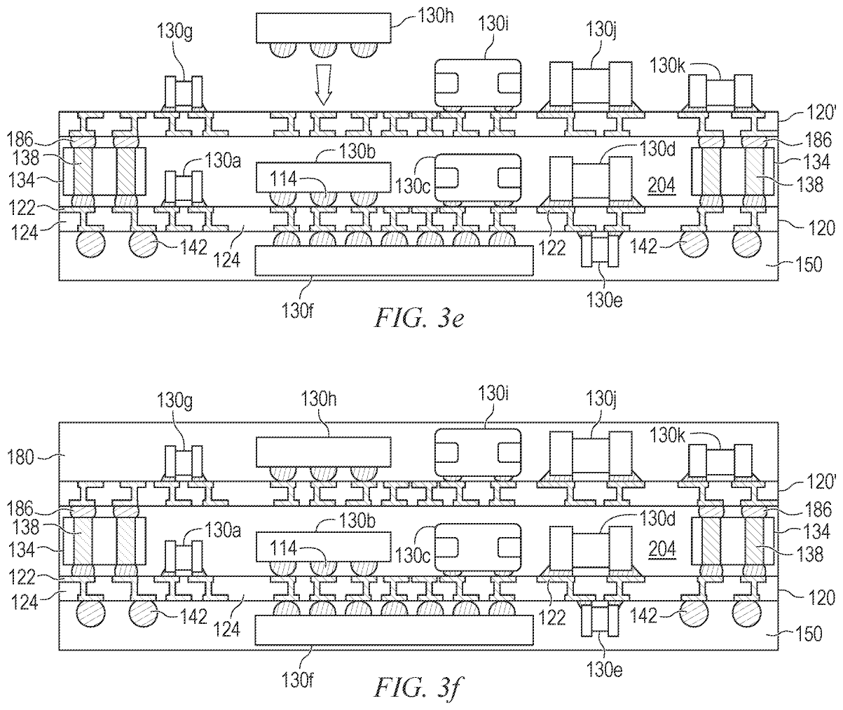

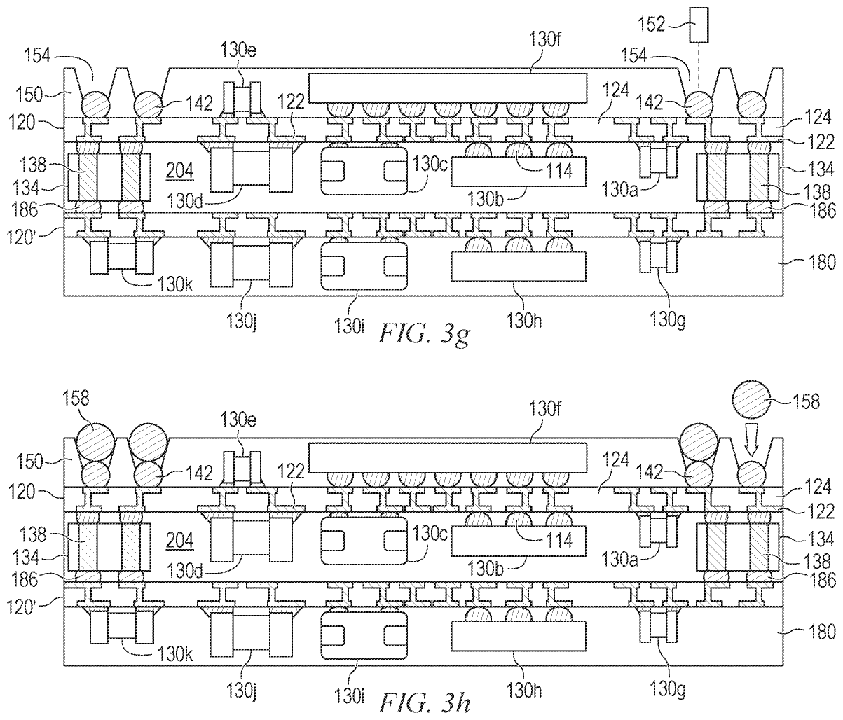

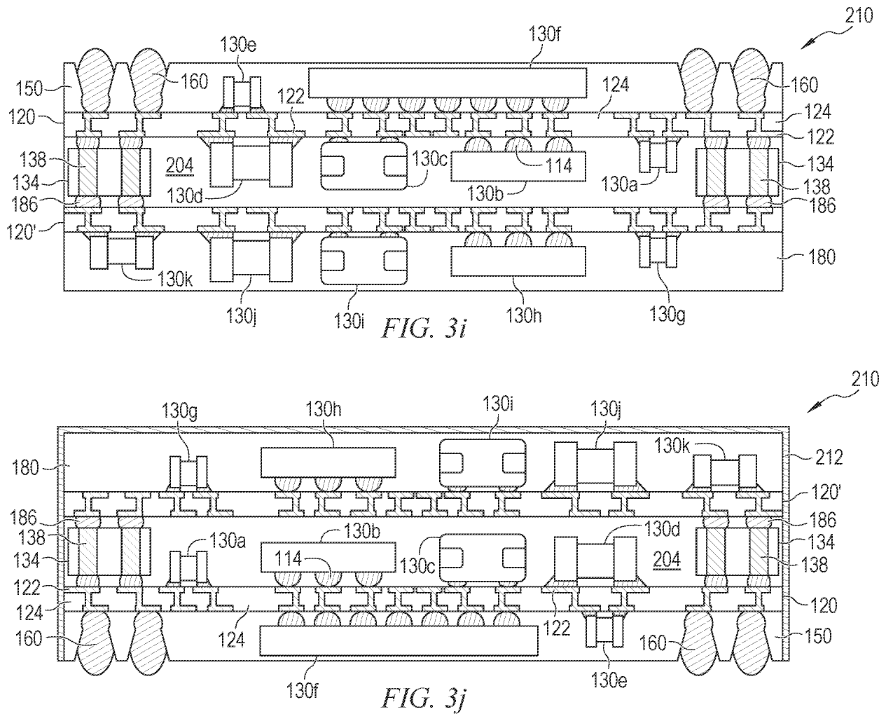

FIGS. 3a-3j illustrate an alternative process flow for forming a three-tier semiconductor package. In FIG. 3a, a process continues from FIG. 2a with components 130a-130d and PCB units 134 mounted to top surface 126 of substrate 120. Substrate 120′ with solder bumps 186 is disposed over substrate 120 and mounted to PCB units 134 by reflowing the solder bumps onto conductive vias 138.

FIG. 3b shows substrate 120′ mounted and connected to substrate 120 through PCB units 134. An encapsulant 204 is deposited between substrates 120 and 120′ using any of the methods and materials described above for encapsulant 140. Encapsulant 204 fills any gaps between components 130a-130d, substrates 120 and 120′, and PCB units 134. Substrate 120′ is mounted prior to encapsulant being deposited over substrate 120, which allows encapsulant 204 to extend completely to each substrate rather than having a gap as in PoP 200.

Substrates 120 and 120′ are flipped in FIG. 3c so that bottom surface 128 of substrate 120 is oriented upward. Electrical components 130e-130f and bumps 142 are disposed on substrate 120 as described above. Encapsulant 150 is deposited over substrate 120 in FIG. 3d as described above. In FIG. 3e, electrical components 130g-130k are mounted to substrate 120′ as described above. Encapsulant 180 is deposited over substrate 120′ in FIG. 3f as described above. Components 130g-130k and encapsulant 180 can be disposed over substrate 120′ prior to mounting the substrates together in FIG. 3a. Openings 154 are formed through encapsulant 150 in FIG. 3g as described above. Openings 154 can be formed prior to mounting components 130g-130k in FIG. 3e. Bumps 158 are disposed in openings 154 in FIG. 3h as described above. Bumps 142 and 158 are reflowed together to form a combined bump 160 in FIG. 3i, as described above.

In FIG. 3i, a three-tier semiconductor package 210 is essentially completed, after being singulated from a panel of devices formed together if necessary. Electrical components 130a-130k are electrically interconnected with each other through substrates 120 and 120′. Bumps 160 provide external interconnection to electrical components 130a-130k. Semiconductor package 210 is formed as a single unitary package rather than a stack of two different submodules as with PoP 200, but otherwise includes the same components and tiers. Additional tiers can be added by interconnecting additional substrates 120 with additional PCB units 134. Semiconductor package 210 is a three-tier system-in-package semiconductor package.

An optional shielding layer 212 is formed over semiconductor package 210 in FIG. 3j. Semiconductor package 210 is flipped so that bumps 160 are oriented downward. Shielding layer 212 is then sputtered, plated, or otherwise formed as described above for shielding layers 164 and 184. Package 210 is singulated prior to forming shielding layer 212 to allow the shielding layer to extend down side surfaces of the package. One or more portions of conductive layers 122 extend to the edge of their respective substrate 120 or 120′ to electrically connected shielding layer 212 to ground. FIGS. 3a-3j illustrate an alternative process flow from FIGS. 2a-2m, which also reduces manufacturing costs and package size relative to the prior art.

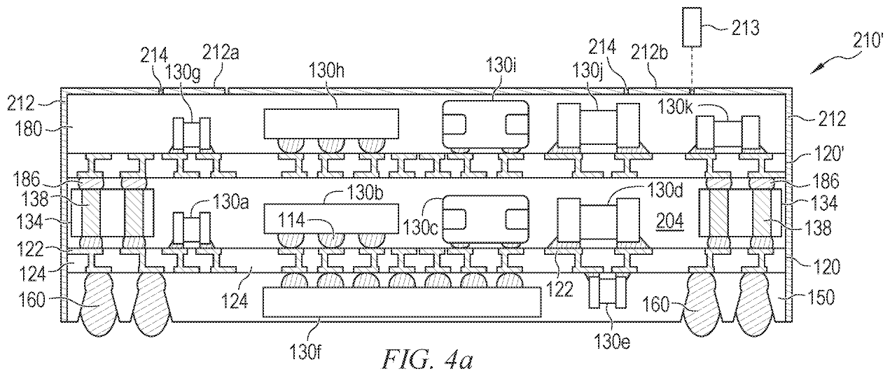

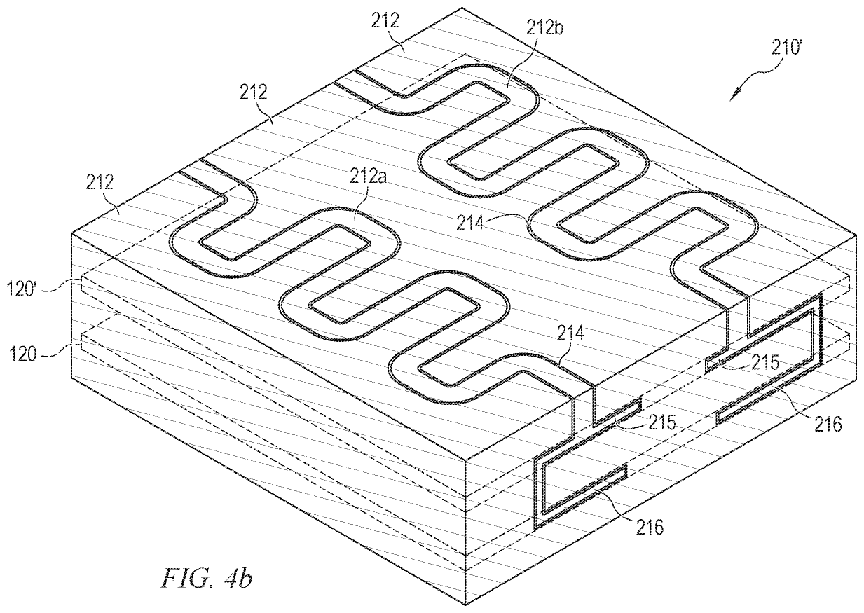

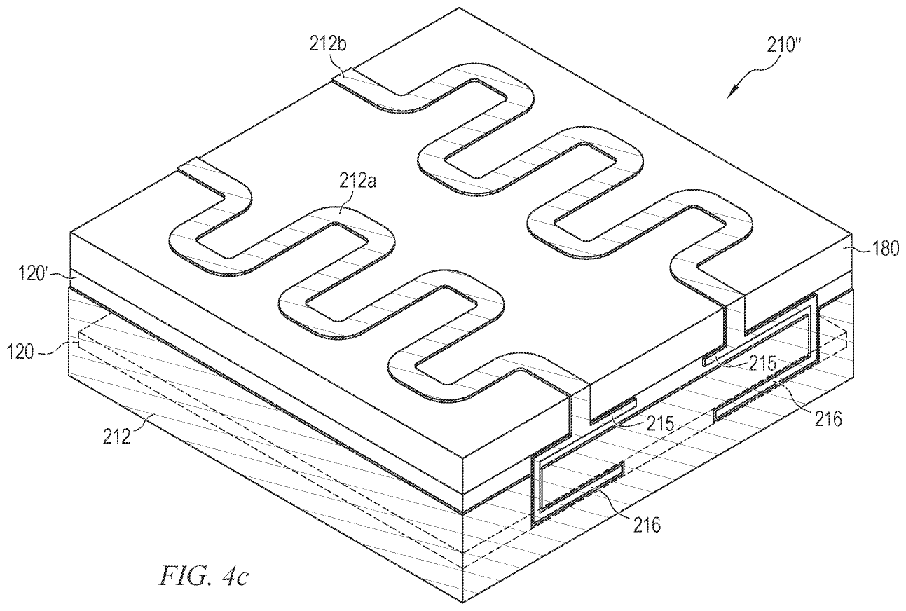

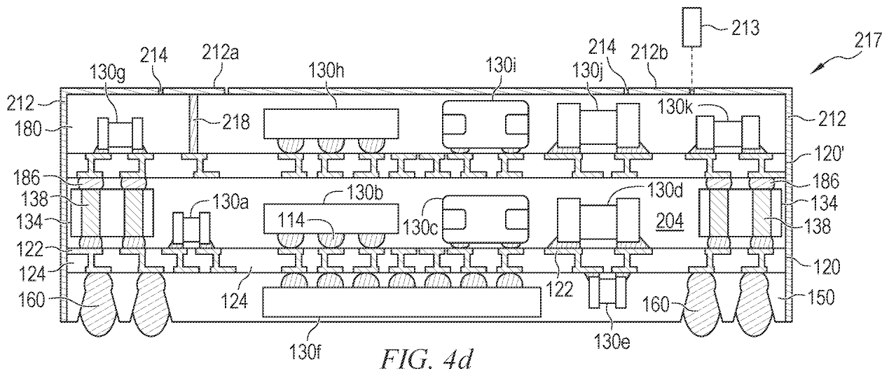

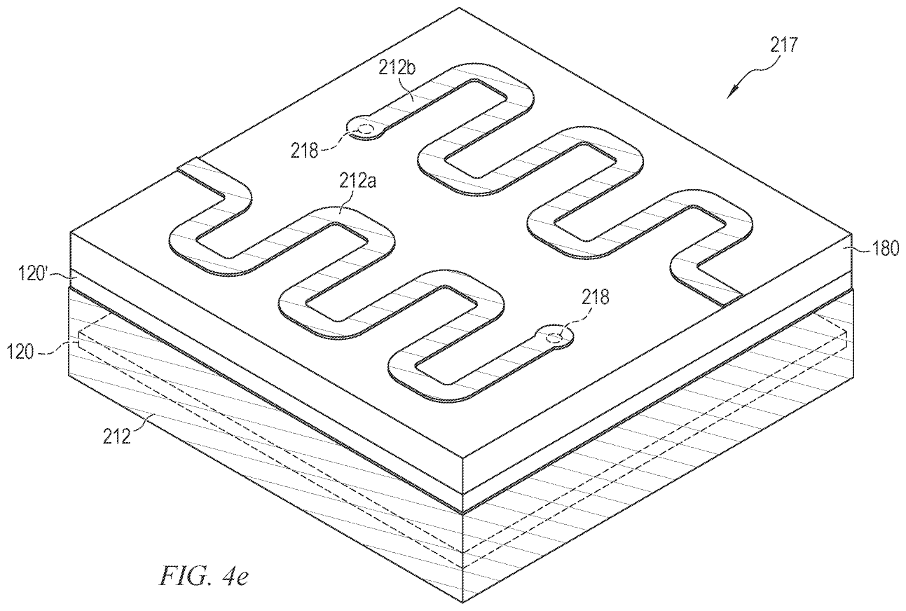

FIGS. 4a-4e illustrate embodiments that can be implemented using additional steps after the stages shown in either FIG. 2m or FIG. 3j. A modified package 210 is shown as semiconductor package 210′ in FIGS. 4a-4c, but a similar idea can be implemented with PoP 200 as well. FIG. 4a shows a laser 213 used to form trenches or channels 214 in and through shielding layer 212 by laser ablation. Chemical or mechanical etching, or another suitable method, is used in other embodiments. Portions 212a and 212b become electrically isolated from the remainder of shielding layer 212. FIG. 4b shows the pattern of channels 214 in perspective view, revealing that the trenches form a pair of antennae 212a and 212b out of shielding layer 212. Antennae 212a and 212b can have any suitable shape depending mostly on the type of antenna and the frequency of the signal being transmitted or received.

Channels 214 also extend down the side surfaces of semiconductor package 210′ to electrically connect antennae 212a and 212b to substrate 120, substrate 120′, or both. A portion 215 of antennae 212a and 212b overlaps an exposed portion of conductive layer 122 within substrate 120′ to electrically connect the antennae to the electrical components 130 on substrate 120′. A portion 216 of antennae 212a and 212b overlaps an exposed portion of conductive layer 122 within substrate 120 to electrically connect the antennae to the electrical components 130 on substrate 120. In some embodiments, one antenna is connected to each substrate and used for different purposes or frequencies. In other embodiments, one or more antennae is connected to both substrates and the usage can be time multiplexed between the different tiers.

In FIG. 4b, shielding layer 212 remains on the top surface of package 210′ surrounding very near antennae 212a and 212b, with only a very narrow channel 214 between the antennae and the remainder of the shielding layer. Such a topology can help with certain antenna types, e.g., microstrips. In other embodiments, such as shown in FIG. 4c, shielding layer 212 is completely removed from the top of package 210″ other than the remaining portions forming antennae 212a and 212b. Shielding layer 212 is also optionally removed from the side surfaces of package 210″ around the top.

FIGS. 4d and 4e illustrate another option where semiconductor package 217 has a conductive via 218 to connect antenna 212a to substrate 120′ instead of being routed through the patterned shielding layer. FIG. 4d shows a cross-sectional view and FIG. 4e shows a perspective view. Conductive via 218 is formed through encapsulant 180 by etching or drilling through the encapsulant and then filling the opening with a conductive material. Conductive material for conductive via 218 and shielding layer 212 is deposited in the same step in some embodiments. In other embodiments, conductive via 218 is a conductive pillar placed on substrate 120′ prior to deposition of encapsulant 180. Conductive via 218 extends from a contact pad of conductive layer 122 on substrate 120′ to the top surface of encapsulant 180. Shielding layer 212 is deposited directly on conductive via 218, and then patterned so that antenna 212a electrically connects to substrate 120′ through the conductive via. Both antennae 212a and 212b can be connected to a via 218, or one can be connected by a via and the other through the patterning of shielding layer 212.

While one exemplary antenna pattern is illustrated, trenches 214 and antennae 212a-212b can be formed in any suitable antenna pattern. While two antennae 212a-212b are shown, any number of antennae can be formed in a similar manner. Antennae 212a and 212b can be formed by etching shielding layer 184 of PoP 200.

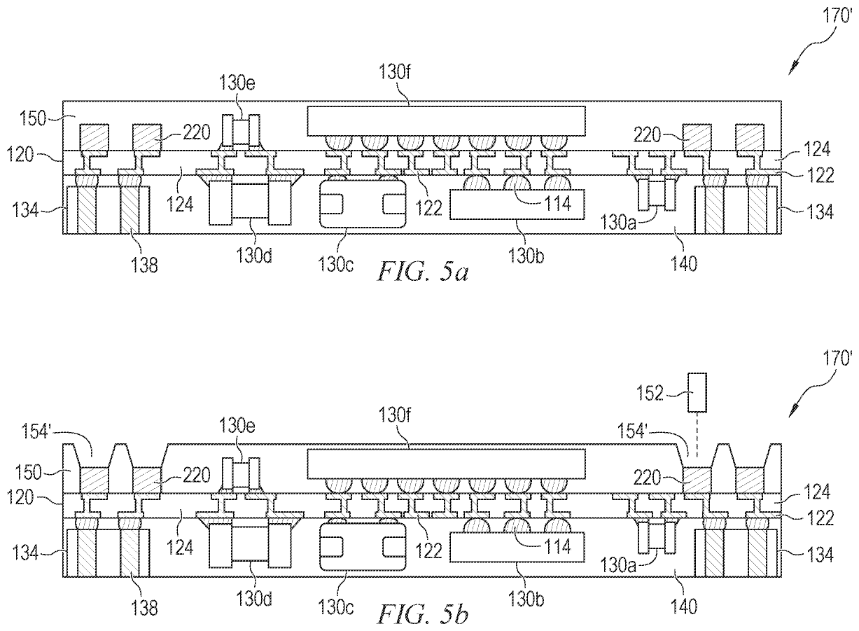

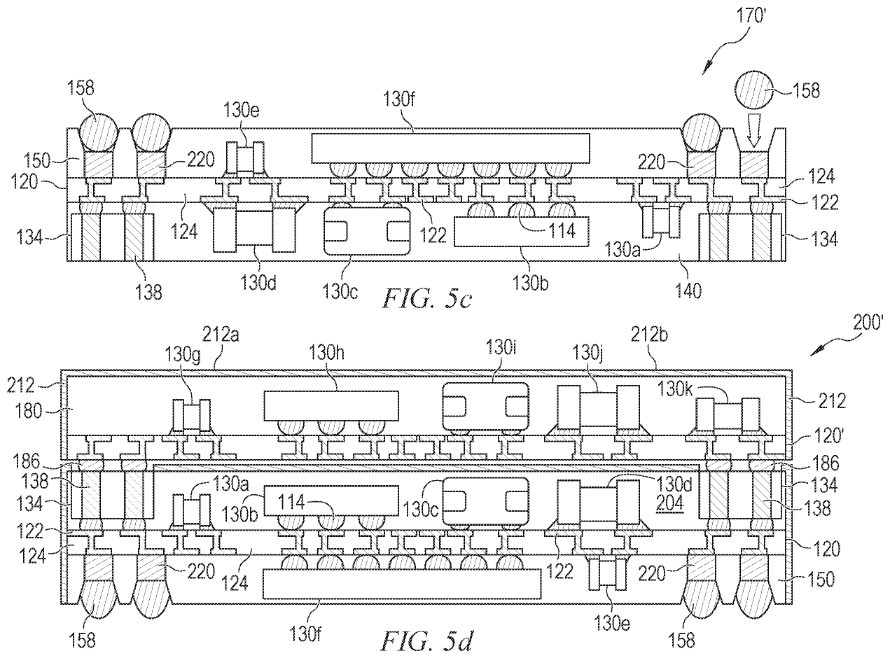

FIGS. 5a-5d illustrate an alternative interconnect structure usage. FIG. 5a shows a PoPb 170′ with solder bumps 142 replaced by conductive pillars 220. Conductive pillars 220 can be formed separately and then picked and placed onto substrate 120 instead of solder bumps 142, in which case a solder paste, conductive adhesive, or other similar substance can be used to mechanically and electrically attach the pillars to the substrate. Alternatively, conductive pillars 220 are a part of conductive layer 122 or otherwise plated to a greater height than insulating layer 124 to form pillars 220. Pillars 220 are formed from copper or another metal that remains solid at normal solder reflow temperatures. Additional layers, such as a wetting or adhesion layer, can be plated onto the copper base material of conductive pillar 220. Pillars 220 can have a cylindrical, cubical, rectangular, polygonal, or other suitable shape.

Openings 154′ are formed through encapsulant 150 to expose a top surface of conductive pillars 220 in FIG. 5b, as described above for openings 154. The bottoms of openings 154′ can have identical footprints to pillars 220 as illustrated, or a larger or smaller footprint.

Bumps 158 are disposed within openings 154′ in FIG. 5c, and then reflowed onto conductive pillars 220 to improve the electrical and mechanical connection. FIG. 5d shows a completed PoP 200′ with conductive pillars 220. Bump 158 is reflowed onto pillar 220 instead of into a combination bump 160. Otherwise, PoP 200′ is formed and operates similarly to PoP 200.

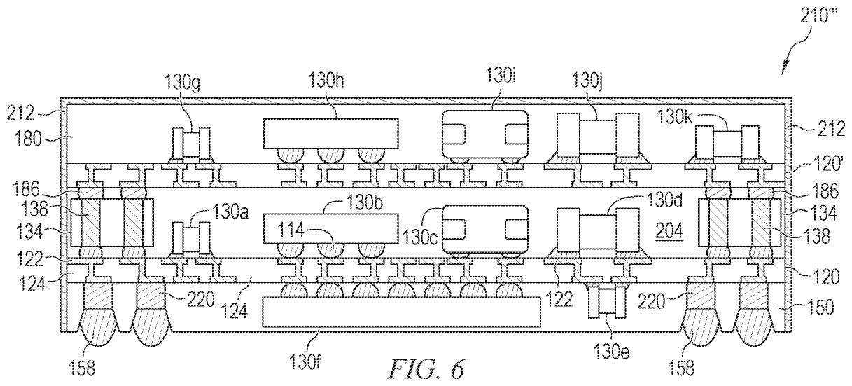

FIG. 6 illustrates a semiconductor package 210′″. Semiconductor package 210′″ is formed and operates similar to semiconductor package 210, except that conductive pillars 220 are used instead of solder bumps 142. Bumps 158 are reflowed onto pillars 220 as described for POP 200′. Either pillars 220 or solder bumps 142 can be used with any of the above or below embodiments.

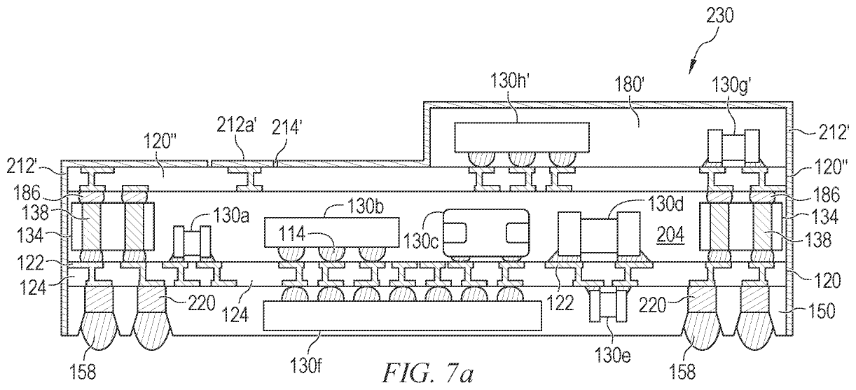

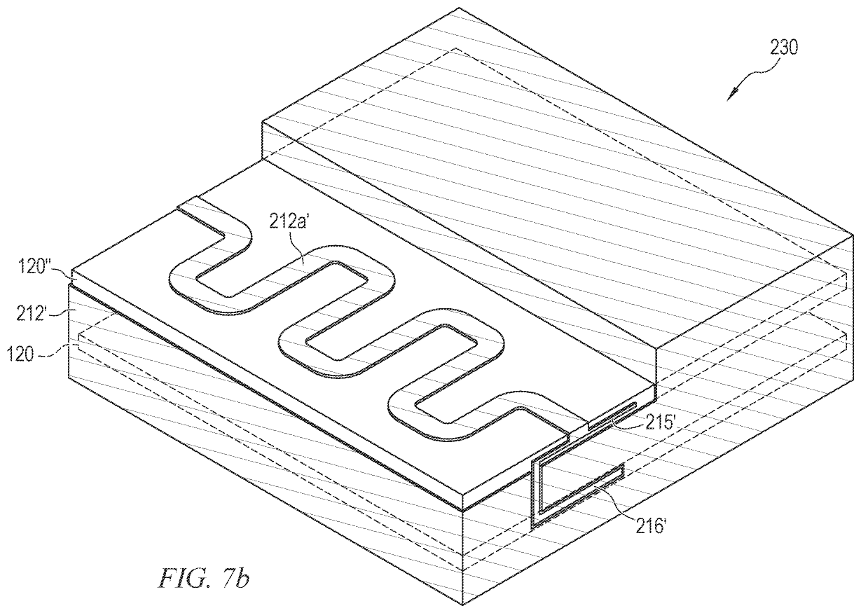

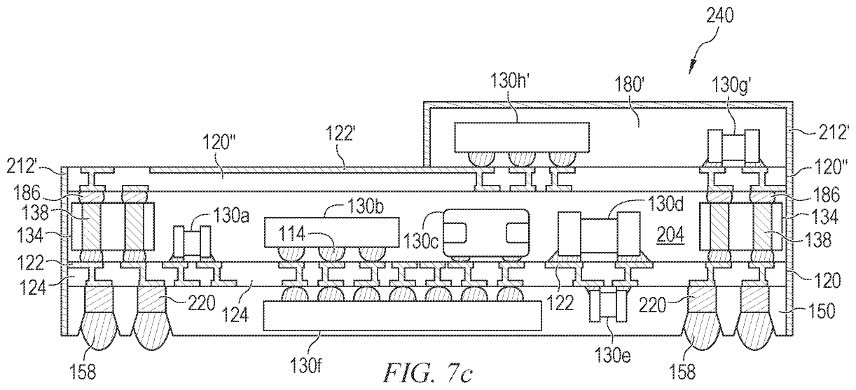

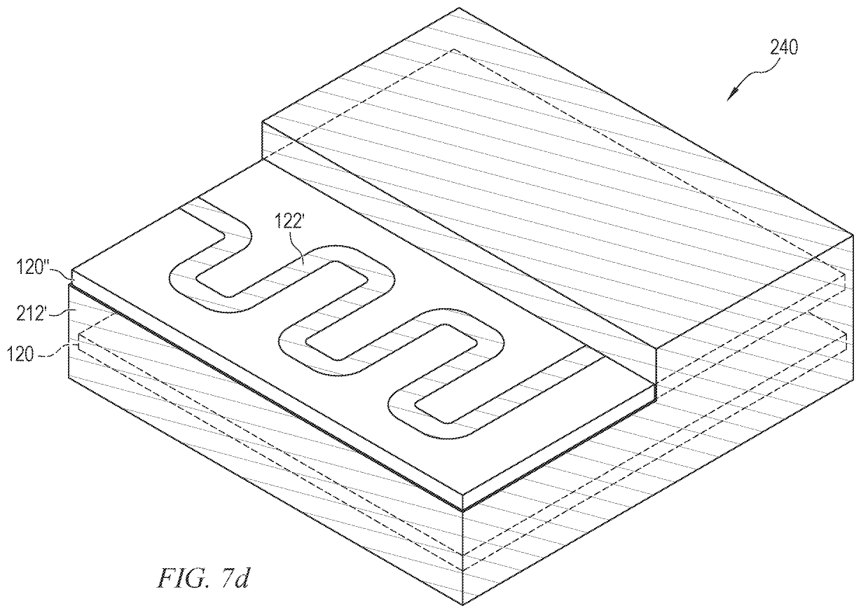

FIGS. 7a and 7b illustrate an embodiment with an antenna 212a′ formed directly on substrate 120 instead of on top of encapsulant 180 as illustrated with antenna 212a above. FIG. 7a is a cross-sectional view while FIG. 7b is a perspective view. When encapsulant 180′ is deposited, a mold is shaped to result in the encapsulant being formed only on a first portion of substrate 120″ while a second portion of the substrate remains exposed from the encapsulant to give the package an overall stepped appearance. Electrical components 130g′ and 130h′ are positioned to ensure that the components are encapsulated.

Shielding layer 212′ is formed as described above for shielding layer 212, except that a part of the shielding layer is formed directly on the exposed portion of substrate 120″. Conductive layer 122 is optionally reconfigured to provide a connection to antenna 212a′ and a ground connection to the remaining shielding layer at the top surface of substrate 120″ as shown in FIG. 7a. Alternatively, or additionally, channel 214′ can be patterned to connect to a side surface of substrate 120″, substrate 120, or both as shown in FIG. 7b. Shielding layer 212′ can remain with only channel 214′ between antenna 212a′ and the rest of the shielding layer as shown in FIG. 7a, or the shielding layer can be completely or partially removed from the top surface of substrate 120″ around the antenna as shown in FIG. 7b. An antennae 212b is also formed on top of encapsulant 180′ in some embodiments.

FIGS. 7c and 7d illustrate an embodiment as semiconductor package 240 with a portion of conductive layer 122 patterned into an antenna 122′. FIG. 7c is a cross-sectional view while FIG. 7d is a perspective view. Conductive layers 122 of substrate 120″ are patterned so that a portion forms an antenna 122′ and also extends to an electrical component, e.g., 130h′, within encapsulant 180′ to give the component use of the antenna. Antenna 122′ can also connect through, e.g., PCB units 134 to components mounted to substrate 120. An insulating layer can be formed between antenna 122′ and shielding layer 212′, where the antenna passes under the shielding layer, to electrically isolate the antenna from the shielding layer. Alternatively, shielding layer 212′ can be patterned or masked off around the antenna to eliminate direct physical and electrical contact to antenna 122′.

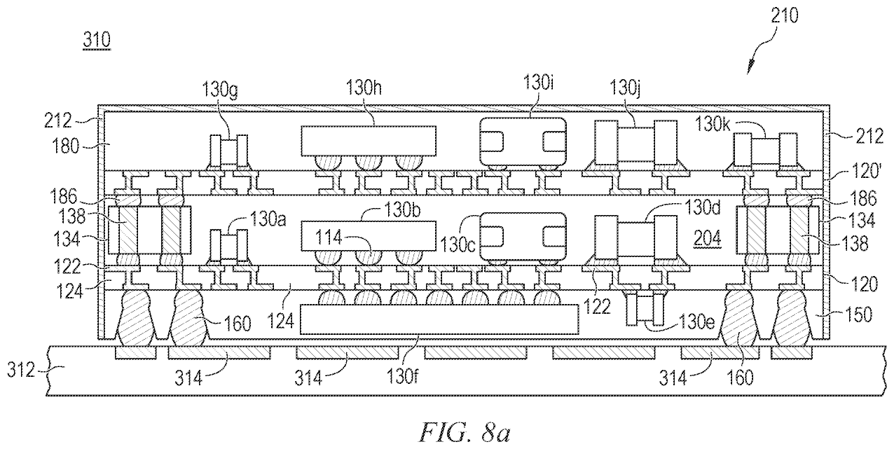

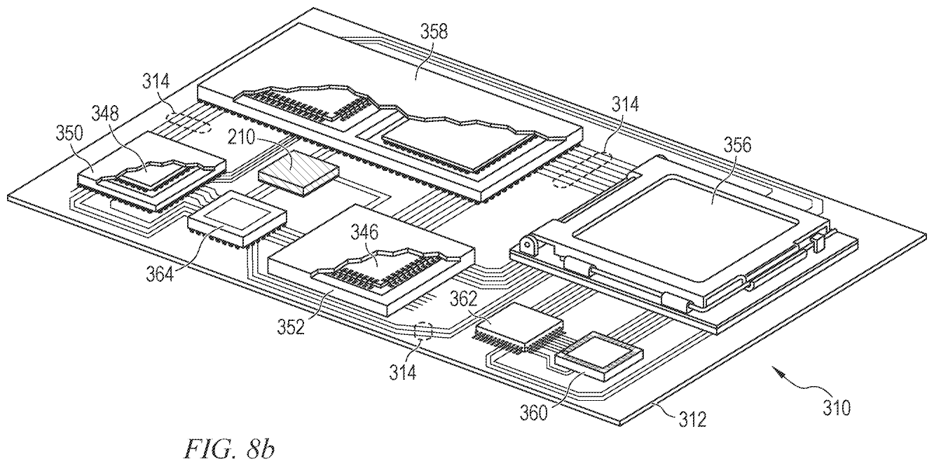

FIGS. 8a and 8b illustrate integrating the above-described semiconductor packages and devices, e.g., semiconductor package 210, into a larger electronic device 310. FIG. 8a illustrates a partial cross-section of semiconductor package 210 mounted onto a printed circuit board (PCB) or other substrate 312 as part of electronic device 310. Bumps 160 are reflowed onto conductive layer 314 of PCB 312 to physically attach and electrically connect semiconductor package 210 to the PCB. In other embodiments, thermocompression or other suitable attachment and connection methods are used. In some embodiments, an adhesive or underfill layer is used between semiconductor package 210 and PCB 312. Electrical components 130a-130k are electrically coupled to conductive layer 314 through bumps 160, substrate 120, PCB units 134, and substrate 120′.

FIG. 8b illustrates electronic device 310 having a chip carrier substrate or PCB 312 with a plurality of semiconductor packages disposed on a surface of PCB 312, including semiconductor package 210. Electronic device 310 can have one type of semiconductor package, or multiple types of semiconductor packages, depending on the application.

Electronic device 310 can be a stand-alone system that uses the semiconductor packages to perform one or more electrical functions. Alternatively, electronic device 310 can be a subcomponent of a larger system. For example, electronic device 310 can be part of a tablet, cellular phone, digital camera, communication system, or other electronic device. Alternatively, electronic device 310 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 312 may have a more irregular shape to fit conveniently into more ergonomic and smaller device shells.

In FIG. 8b, PCB 312 provides a general substrate for structural support and electrical interconnect of the semiconductor packages disposed on the PCB. Conductive signal traces 314 are formed over a surface or within layers of PCB 312 using evaporation, electrolytic plating, electroless plating, screen printing, or other suitable metal deposition process. Signal traces 314 provide for electrical communication between each of the semiconductor packages, mounted components, and other external system components. Traces 314 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 312. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 312. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 312. In some embodiments, electronic device 310 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims. Method steps can be performed in any suitable order where the steps have no apparent dependency upon each other. The specific order of manufacturing steps illustrated is not important except where explicitly stated in the specification or recited in the claims.

What is claimed:

1. A semiconductor device, comprising:
a first substrate;
a first electrical component disposed over a first surface of the first substrate;
a first encapsulant deposited over the first electrical component and first surface of the first substrate;
a modular interconnect unit disposed over a second surface of the first substrate;
a second encapsulant deposited over the second surface of the first substrate; and
a second substrate disposed over the second surface of the first substrate and electrically connected to the first substrate through the modular interconnect unit.

2. The semiconductor device of claim 1, wherein the second encapsulant extends to a surface of the second substrate.

3. The semiconductor device of claim 1, further including a second electrical component disposed over the second surface of the first substrate within the second encapsulant.

4. The semiconductor device of claim 3, further including:
a third electrical component disposed over the second substrate; and
a third encapsulant deposited over the second substrate and third electrical component.

5. The semiconductor device of claim 1, further including a shielding layer formed over the second substrate.

6. The semiconductor device of claim 5, wherein the shielding layer is etched to form an antenna.

7. A semiconductor device, comprising:
a first substrate;
a first electrical component disposed over a first surface of the first substrate;
a modular interconnect unit disposed over a second surface of the first substrate; and
a second substrate disposed over the second surface of the first substrate and electrically connected to the first substrate through the modular interconnect unit.

8. The semiconductor device of claim 7, further including a second electrical component disposed over the second surface of the first substrate.

9. The semiconductor device of claim 8, further including a third electrical component disposed over the second substrate.

10. The semiconductor device of claim 7, further including a shielding layer formed over the second substrate.

11. The semiconductor device of claim 10, further including a second shielding layer formed between the first substrate and second substrate.

12. The semiconductor device of claim 10, wherein the shielding layer is etched to form an antenna.

13. The semiconductor device of claim 12, further including an encapsulant disposed between the shielding layer and a first portion of the second substrate, wherein the antenna is formed directly on a second portion of the second substrate.

14. A method of making a semiconductor device, comprising:
providing a first substrate;
disposing a first electrical component over a first surface of the first substrate;
depositing a first encapsulant over the first electrical component and first surface of the first substrate;
disposing a modular interconnect unit over a second surface of the first substrate;
depositing a second encapsulant over the second surface of the first substrate; and
disposing a second substrate over the second surface of the first substrate, wherein the second substrate is electrically connected to the first substrate through the modular interconnect unit.

15. The method of claim 14, further including forming a shielding layer over the second substrate.

16. The method of claim 15, further including etching the shielding layer to form an antenna.

17. The method of claim 14, further including:
disposing a second electrical component over the second surface of the first substrate;
depositing the second encapsulant over the second electrical component;
disposing a third electrical component over the second substrate; and
depositing a third encapsulant over the second substrate and third electrical component.

18. The method of claim 17, further including depositing the first encapsulant, second encapsulant, and third encapsulant prior to disposing the second substrate over the first substrate.

19. The method of claim 14, further including:
disposing a first solder on the first surface of the first substrate;
depositing the first encapsulant over the first solder;
forming an opening through the first encapsulant to expose the first solder;
disposing a second solder in the opening; and
reflowing the first solder and second solder.

20. A method of making a semiconductor device, comprising:
providing a first substrate;
disposing a first electrical component over a first surface of the first substrate;
disposing a modular interconnect unit over a second surface of the first substrate; and
disposing a second substrate over the second surface of the first substrate and electrically connected to the first substrate through the modular interconnect unit.

21. The method of claim 20, further including:
disposing a second electrical component over the second surface of the first substrate; and
disposing a third electrical component over the second substrate.

22. The method of claim 20, further including forming a shielding layer over the second substrate.

23. The method of claim 22, further including patterning the shielding layer to form an antenna.

24. The method of claim 22, further including:
depositing an encapsulant over the second substrate; and
forming the shielding layer over the encapsulant.

25. The method of claim 20, further including:
disposing a solder on the second substrate; and
reflowing the solder onto the modular interconnect unit.
